(19) United States
(12) Patent Application Publication
(10) Pub. No.: US 2019/0181032 A1
(43) Pub. Date: Jun. 13, 2019

(54) SEMICONDUCTOR DEVICE AND MANUFACTURING METHOD THEREOF

(71) Applicant: HUAIAN IMAGING DEVICE MANUFACTURER CORPORATION, Huaian (CN)

(72) Inventors: Yosuke KITAMURA, Huaian (CN); Amane OISHI, Huaian (CN); Xiaolu HUANG, Huaian (CN)

(73) Assignee: HUAIAN IMAGING DEVICE MANUFACTURER CORPORATION, Huaian (CN)

(21) Appl. No.: 16/003,501

(22) Filed: Jun. 8, 2018

(30) Foreign Application Priority Data
Dec. 7, 2017 (CN) 201711281228.2

(51) Int. Cl. H01L 21/74; H01L 23/535; H01L 21/762; H01L 29/66

(52) U.S. Cl. CPC H01L 21/743; H01L 29/66568; H01L 21/76224; H01L 23/535

(57) ABSTRACT

A semiconductor device comprises a substrate, the substrate including a trench structure component and active regions separated by the trench structure component, wherein, the trench structure component has a trench and a first region and a second region located in the trench, the second region at least encloses a bottom surface and a side surface of the first region, the first region is made of a conductive material, and the second region is made of an insulating material.

### CROSS-REFERENCE TO RELATED APPLICATIONS

This application claims priority to Chinese Patent Application No. 201711281228.2, filed on Dec. 7, 2017, which is hereby incorporated by reference in its entirety.

### TECHNICAL FIELD

The present disclosure relates generally to the field of semiconductor, and more particularly, to a semiconductor device and a method of manufacturing the same.

### BACKGROUND

With the rapid development of semiconductor technologies, integrated circuits are heading for a higher element density in order to reach a faster operation speed, a larger data storage amount, and more functions. Accordingly, an integration of individual devices and/or elements into a limited space, especially a flexible design of integrated circuits and an optimization of the integration process, is increasingly challenging.

An isolation region is a component provided between two adjacent semiconductor devices for isolating an undesired leakage current. Trench isolation is a common specific implementation of the isolation region, and capable of largely reducing an isolation area so as to lower the cost of an entire chip. A method of manufacturing the isolation region generally comprises trench etching, insulating material filling, and insulating material planarization. By filling the trench provided between two adjacent semiconductor devices with an insulating material, electrical isolation between the adjacent semiconductor devices can be achieved.

Accordingly, there is a need for new technologies.

### SUMMARY

One of aims of the present disclosure is to provide a novel semiconductor device and method of manufacturing the same, and particularly, relates to enhance flexibility of design of integrated circuits by means of a trench isolation structure.

A first aspect of this disclosure is to provide a semiconductor device, comprising a substrate, the substrate including a trench structure component and active regions separated by the trench structure component, wherein the trench structure component has a trench and a first region and a second region located in the trench, the second region at least encloses a bottom surface and a side surface of the first region, and wherein the first region is made of a conductive material, the second region is made of an insulating material.

A second aspect of this disclosure is to provide a method of manufacturing the semiconductor device, comprising: providing a substrate, the substrate including a trench and active regions separated by the trench; forming a first insulating layer on the substrate, the first insulating layer overlaying a surface of the trench and the active regions; and forming a first region on the first insulating layer, the first region being located in the trench and made of a conductive material.

A third aspect of this disclosure is to provide a method of manufacturing the semiconductor device, comprising: providing a substrate, the substrate including a trench and active regions separated by the trench; filling the trench to form a first insulating layer; forming an oxide layer on the substrate, the oxide layer overlaying the active regions and the first insulating layer; forming an opening through the oxide layer and a portion of the first insulating layer; forming a conductive layer on the oxide layer, the conductive layer overlaying the oxide layer and filling the opening; and etching a portion of the conductive layer that is in the opening to form a first region on the first insulating layer in the opening.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a component of the specification, illustrate embodiments of the present disclosure and, together with the description, serve to explain the principles of the present disclosure.

The present disclosure will be better understood according the following detailed description with reference of the accompanying drawings.

FIG. 1 illustrates a schematic sectional diagram of the semiconductor device according to one or more exemplary embodiments of this disclosure.

FIG. 2 illustrates a flow diagram of the method of manufacturing the semiconductor device according to one or more exemplary embodiments of this disclosure.

FIGS. 3A to 3G illustrate schematic sectional diagrams of the semiconductor device corresponding to a portion of steps of the method as shown in FIG. 2.

FIGS. 4A to 4D illustrate schematic sectional diagrams of the semiconductor device corresponding to a portion of steps of the method as shown in FIG. 2.

FIG. 5 illustrate a schematic sectional diagram of the semiconductor device according to one or more other exemplary embodiments of this disclosure.

FIG. 6 illustrates a flow diagram of the method of manufacturing the semiconductor device according to one or more other exemplary embodiments of this disclosure.

FIGS. 7A to 7F illustrate schematic sectional diagrams of the semiconductor device corresponding to a portion of steps of the method as shown in FIG. 6.

FIG. 8 illustrates a schematic top diagram of a portion of the semiconductor device according to one or more exemplary embodiments of this disclosure.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a component of the specification where appropriate.

In all of the examples as illustrated and discussed herein, any specific values should be interpreted to be illustrative only and non-limiting. Thus, other examples of the exemplary embodiments could have different values.

In this Description, the “semiconductor device” is directed to any device of which a portion or an entirety can operate by utilizing semiconductor characteristics of a semiconductor element. For example, a semiconductor device may be one or more of an image sensor, a memory, and a logic circuit.

The inventor of the present application recognizes that, the wiring on a conventional semiconductor device is insufficiently flexible, and takes much space.

Accordingly, there is a need for new wiring technologies in the art, so as to enhance flexibility of design of integrated circuits and/or reduce a size of the chip.

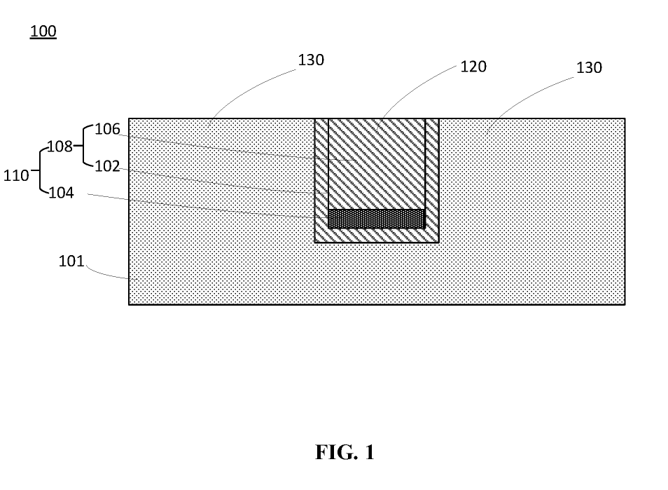

FIG. 1 illustrates a schematic sectional diagram of the semiconductor device according to one or more exemplary embodiments of this disclosure.

As shown in FIG. 1, a semiconductor device 100 comprises a substrate 101. Examples of a material of the substrate 101 may include, but be not limited to, a unitary semiconductor material (such as silicon or germanium, etc.), a compound semiconductor material (such as silicon carbide, silicon-germanium, gallium arsenide, gallium phosphide, indium phosphide, indium arsenide, and/or indium antimonide), or combinations thereof. In some other embodiments, the substrate may also be a Silicon-on-Insulator (SOI), a Silicon-Germanium-on-Insulator, or other composite substrate. Those skilled in the art will understand that the substrate is not limited and may be selected according to practical applications. In the substrate, other member of the semiconductor device may be formed, for example, other member formed in a previous processing step.

As shown in FIG. 1, the substrate 101 may include a trench structure component 110 and active regions 130 separated by the trench structure component 110.

The active region 130 may be configured to form an active device (not illustrated). For example, in some exemplary embodiments, a semiconductor device such as a MOS transistor may be formed in the active region 130. Isolation may be achieved between active devices by the trench structure component 110. Although the figure only illustrates one trench structure component 110 and corresponding active regions 130 which are separated by the trench structure component 110 so as to simplify the description, those skilled in the art will easily understand, without deviating from the scope of this disclosure, that any number of trench structure components 110 and corresponding active regions 130 may be formed in the substrate 101 according to requirements of practical applications.

As shown in FIG. 1, the trench structure component 110 may include a trench 120. For example, in some exemplary embodiments, the trench 120 may be formed by a trench etching step in the Shallow Trench Isolation (STI) process. Although the trench 120 as illustrated is provided to be substantially perpendicular to a surface of the substrate 101, those skilled in the art should understand that, an inclination angle of the trench 120 is not limited thereto.

The trench structure component 110 further includes a first region 104 and a second region 108 formed in the trench 120. It should be understood that, although respective portions of the trench structure component 110 in FIG. 1 are illustrated as having a uniform thickness, it is not limited thereto.

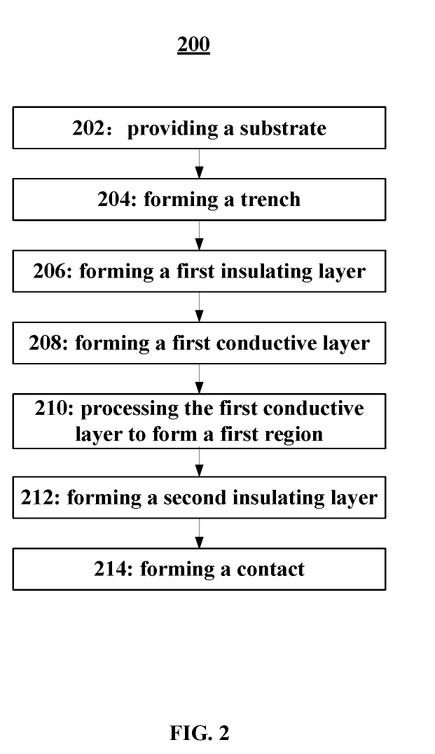

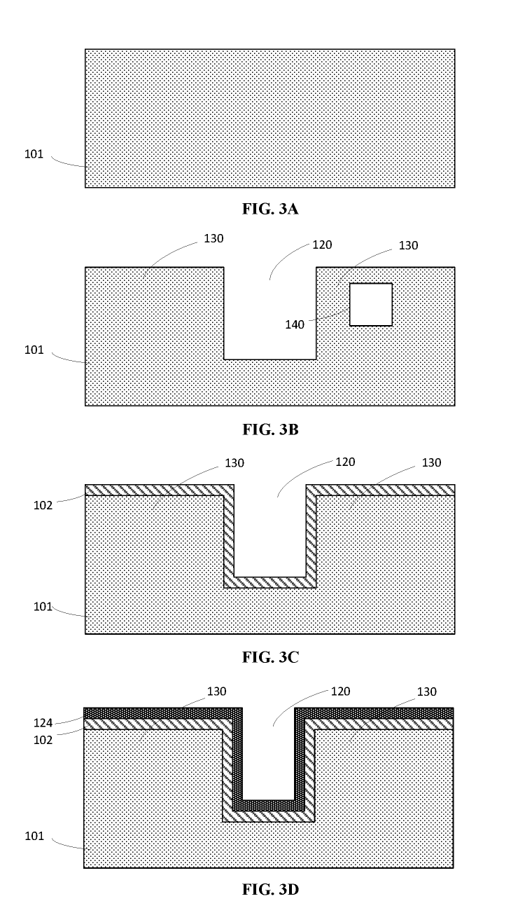

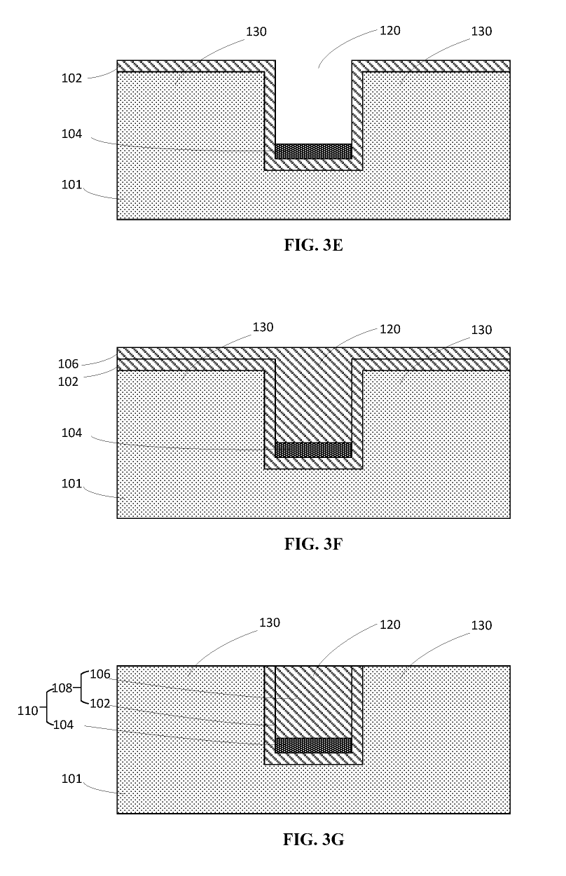

The second region 108 may at least enclose a bottom surface and a side surface of the first region 104. In some exemplary embodiments, as shown in FIG. 1, the second region 108 may enclose an entirety of the first region 104. For example, the second region 108 may be composed of a first insulating layer 102 and a second insulating layer 106. Alternatively, in some exemplary embodiments, the second region 108 may enclose only a portion of the first region 104. For example, the second region 108 may only enclose a bottom surface and a side surface of the first region 104 but not overlay a top surface of the first region 104 (refer to FIG. 3E). In this case, the second region 108 may be composed of, for example the first insulating layer 102, and the top surface of the first region 104 may be flush with or lower than the top surface of the substrate 101. It may be understood that, a sectional shape of the first region 104 is not limited to the rectangle as shown, but may have various shapes according to requirements or according to the process, as long as it can be isolated from any active regions 130 by the insulating layer.

The first region 104 may be formed of a conductive material, and the second region 108 may be formed of an insulating material. A material that forms the first region 104 may be a typical polysilicon material, for example but not limited to, a boron-doped polysilicon. A material that forms the second region 108 may be a typical oxide insulating material, for example but not limited to, hafnium oxide, lanthanum oxide, or zirconium oxide.

Since the second region 108 formed in the trench 120 is insulative, the trench 120 still can achieve the electrical isolation for the active regions 130. Besides, since the first region 104 enclosed by the second region 108 is made of a conductive material, the first region 104 may serve as the wiring. Specifically speaking, the trench structure component 110 may serve both the isolating and wiring functions at the same time. Therefore, by using the way of wiring as described in this exemplary embodiment, an ability of flexible design of integrated circuits may be effectively improved, and a size of the chip is likely to be further reduced.

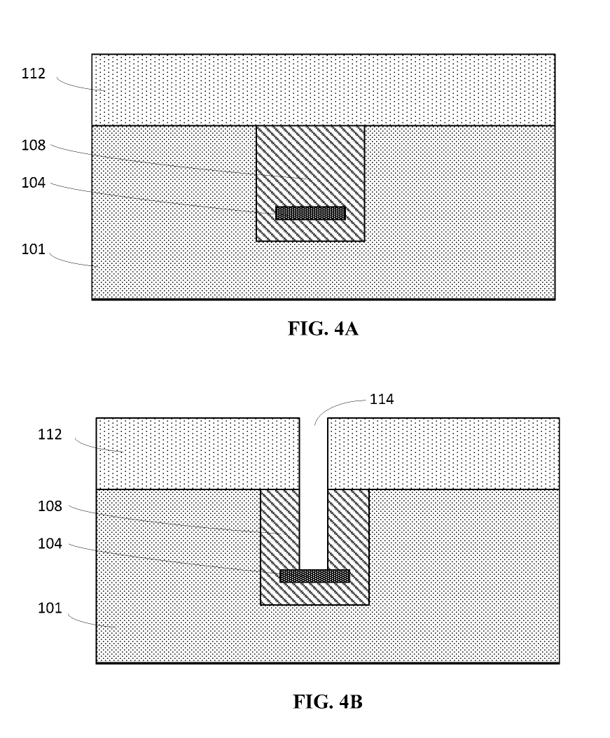

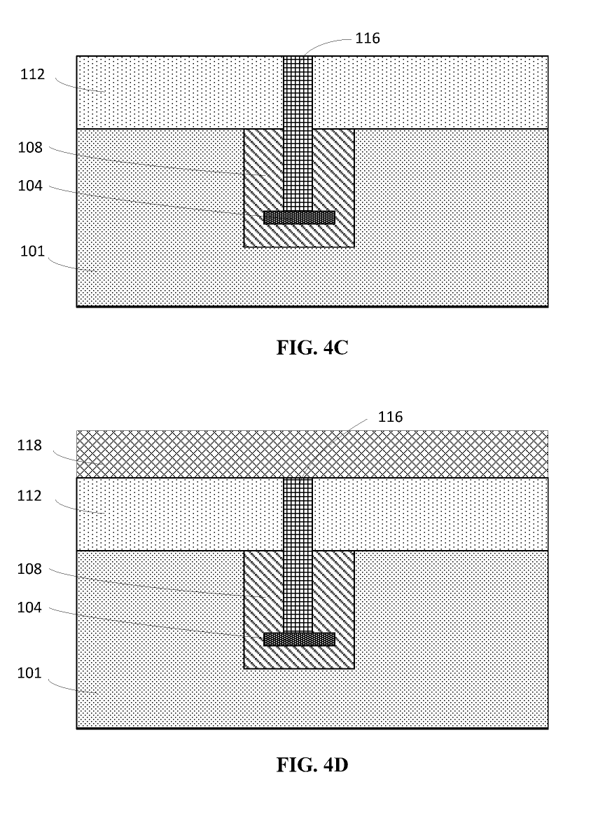

FIG. 2 illustrates a flow diagram of the method of manufacturing the semiconductor device according to one or more exemplary embodiments of this disclosure. FIGS. 3A-3G and 4A-4D are respective schematic sectional diagrams of the semiconductor device corresponding to a portion of steps of the method as shown in FIG. 2. Explanations will be given below by combining FIGS. 3A-3G and 4A-4D with FIG. 2

At step 202, a substrate is provided (for example, a substrate 101 of FIG. 3A).

At step 204, a trench 120 may be formed in the substrate 101 (see FIG. 3B). Accordingly, a substrate 101 including a trench 120 and active regions 130 separated by the trench 120 is provided. The active region 130 may be configured to form an active device. For example, in some exemplary embodiments, a semiconductor device such as a MOS transistor 140 may be formed in the active region 130.

In one or more exemplary embodiments, the trench 120 is formed by etching the substrate 101. It may be completed by using any appropriate etching method that is known in the art, which includes, but is not limited to, utilizing a patterned mask (for example, a photoresist or a hard mask). Any known appropriate etching process may be used herein, such as wet etching or dry etching (e.g. plasma etching). The formed trench 120 separates respective active regions 130 on the substrate 101 from each other.

At step 206, a first insulating layer 102 may be formed in the trench (see FIG. 3C).

As shown in FIG. 3C, the first insulating layer 102 includes a portion formed on the active regions 130 and a portion formed on an inner surface of the trench 120. In one or more exemplary embodiments, the first insulating layer 102 includes an insulating material such as an oxide. The first insulating layer 102 may be formed by the Chemical Vapor Deposition (CVD), the furnace thermal oxidation process, or other appropriate technology.

Thereafter, a conductive first region located in the trench 120 may be formed on the first insulating layer 102. According to one or more exemplary embodiments, the first region may be formed by steps 208 and 210. A more specific illustrative description will be given below

At step 208, a first conductive layer 124 is formed on the first insulating layer 102.

The first conductive layer 124 may overlay the first insulating layer 102. As an example, as shown in FIG. 3D, the first conductive layer 124 may include a portion formed over the active regions 130 and a portion formed over the inner surface of the trench 120. Optionally, the first conductive layer 124 may be conformally formed over the trench 120. In one or more exemplary embodiments, the first conductive layer 124 includes a conductive material, for example, polysilicon (such as highly doped polysilicon). The first region 104 may be formed by the Chemical Vapor Deposition (CVD), the Plasma Enhanced Chemical Vapor Deposition (PECVD) process, or other appropriate technology.

At step 210, the first region 104 is generated by processing the first conductive layer 124. The first region 104 may serve a wiring function. It can be understood that, the first region 104 can be formed in a manner which is not limited to the above one, and those skilled in the art may form the first region 104 on the first insulating layer 102 in the trench 120 in a different manner. Further, although FIG. 3E illustrates that the first region 104 fills only a portion of the trench, the first region 104 may also fill the entire trench.

In this exemplary embodiment, the first region 104 may be formed by two substeps. First of all, a patterned mask (for example, a photoresist or a hard mask) is formed on the first conductive layer 124 in the trench 120 (not illustrated). Next, a selective etching is performed for the first conductive layer 124. In one or more exemplary embodiments, after being etched, only a portion of the first conductive layer 124 near the bottom of the trench 120 is reserved and forms the first region 104, as shown in FIG. 3E. In one or more other exemplary embodiments, the etching process removes only a portion of the first conductive layer 124 that is outside the trench 120, and a remaining portion of the first conductive layer 124 (a portion located on a bottom wall and a side wall of the trench 120) forms the first region 104 (not shown).

After the first region 104 is formed, the trench 120 filled with the first insulating layer 102 and the conductive first region 104 forms the trench structure component 110, which may serve both the isolating and wiring functions at the same time, and enhance the flexibility of design of the semiconductor device.

In some exemplary embodiments, optionally, the step 212 of forming a second insulating layer 106 may be performed after the first region 104 is formed, as shown in FIG. 3F. In this case, the second insulating layer 106 may include a portion overlaying the first region 104 and a portion overlaying the first insulating layer 102.

In some exemplary embodiments, optionally, portions of the first insulating layer 102 and the second insulating layer 106 that are outside the trench 120 may be removed, as shown in FIG. 3G. For example, in one or more exemplary embodiments, the removal may be achieved by the Chemical Mechanical Polishing (CMP) process, and subsequently a smooth planarized surface is formed. In this way, remaining portions of the first insulating layer 102 and the second insulating layer 106 form in the trench 120 a second region 108 that encloses the first region 104.

In some exemplary embodiments, optionally, the step 214 of forming a contact 116 may be performed after the first region 104 is formed. The contact 116 is used for connecting the first region 104 with other conductive component or conductive material. For example, in some exemplary embodiments, the contact 116 may connect the first region with an element (for example, a pad) which needs to be connected to the wiring (for example, ground lines). It needs to be understood that, the contact 116 may be formed after the structure as shown in FIG. 3E is obtained, or after the structure as shown in FIG. 3G is obtained. The formation of a contact based on the structure as shown in FIG. 3G is taken as an example for illustrative explanations below.

In some exemplary embodiments, the contact 116 may be formed by several substeps as follows.

First of all, as shown in FIG. 4A, a dielectric layer 112 is formed on the substrate 101. In some exemplary embodiments, the dielectric layer 112 may be multiple layers. For example, in some exemplary embodiments, the dielectric layer 112 may be a multilayer insulating material. In one or more exemplary embodiments, optionally, respective layers of the dielectric layer 112 may be planarized by the Chemical Mechanical Polishing process to form a smooth planarized surface. As shown in FIG. 4A, in one or more exemplary embodiments, the dielectric layer 112 may include a first portion overlaying the substrate 101 and a second portion overlaying the filled trench.

Thereafter, as shown in FIG. 4B, an opening 114 down to an upper surface of the first region 104 is manufactured from an upper surface of the second portion of the dielectric layer 112 that overlays the filled trench. For example, in some exemplary embodiments, the opening 114 may be obtained by any appropriate etching process that is known in the art, which includes, but is not limited to, wet etching or dry etching (e.g. plasma etching).

Thereafter, as shown in FIG. 4C, a contact 116 through down to the upper surface of the first region 104 is formed in the opening 114. In some exemplary embodiments, the contact 116 may be made of a conductive material. A material that forms the contact 116 may be a typical metal material, for example but not limited to, tungsten.

In addition, as shown in FIG. 4D, a metal interconnect layer 118 may be formed on the dielectric layer 112.

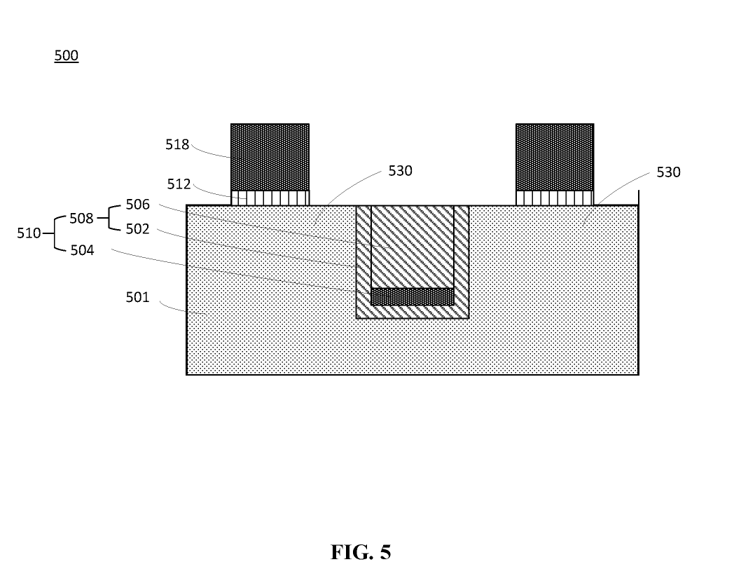

FIG. 5 illustrate a schematic sectional diagram of the semiconductor device according to one or more other exemplary embodiments of this disclosure. To simplify the description, in the description for respective exemplary embodiments according to this disclosure, a detailed description is given below only for a difference between exemplary embodiments, but a repetitive explanation for identical or similar portions is omitted.

As shown in FIG. 5, a semiconductor device 500 comprises a substrate 501, a trench structure component 510 (for example, include at least a first region 504 and a second region 508), active regions 530 separated by the trench structure component 510, an oxide layer 512, and a gate structure 518. In particular, the substrate 501, the trench structure component 510, and the active regions 530 are similar to corresponding components of the semiconductor device 100 as shown in FIG. 1, and thus explanations therefor are omitted here.

The semiconductor device 500 further comprises an oxide layer 512 formed on the substrate 501. For example, in some exemplary embodiments, the oxide layer 512 is formed on the active regions 530 included in the substrate 501. A material that forms the oxide layer 512 may be a typical oxide material, for example but not limited to, hafnium oxide, lanthanum oxide, or zirconium oxide. In some exemplary embodiments, the oxide layer 512 may be multiple layers. In one or more exemplary embodiments, optionally, respective layers of the oxide layer 512 are planarized by the Chemical Mechanical Polishing process to form a smooth planarized surface.

The semiconductor device 500 further comprises a gate structure 518 formed on the oxide layer 512. In some exemplary embodiments, the gate structure 518 may be made of a conductive material. A material that forms the gate structure 518 may be a typical polysilicon material, for example but not limited to, boron-doped polysilicon.

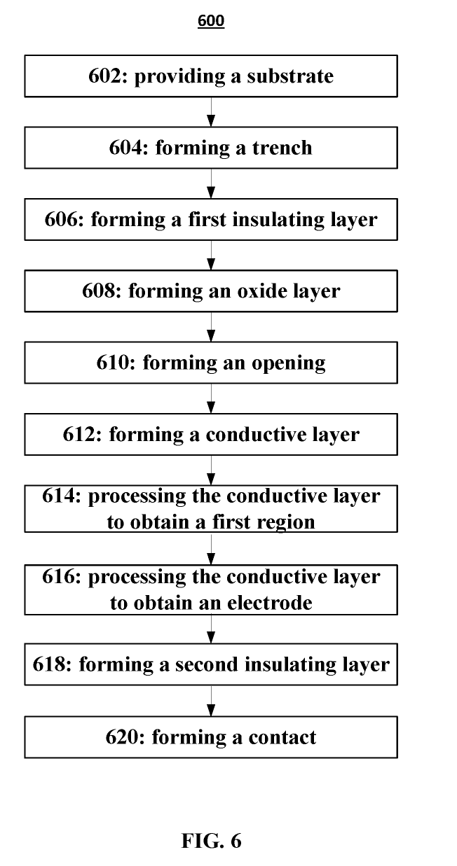

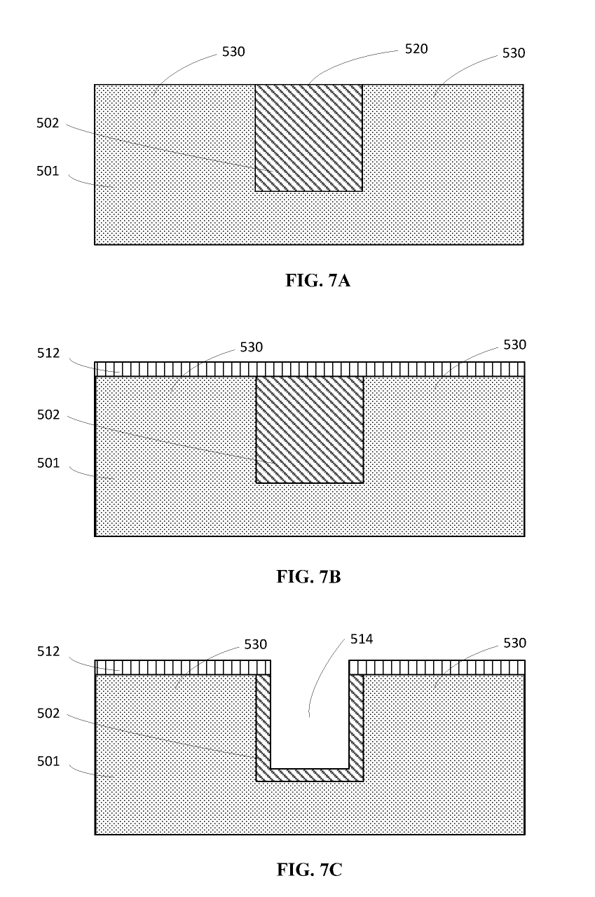

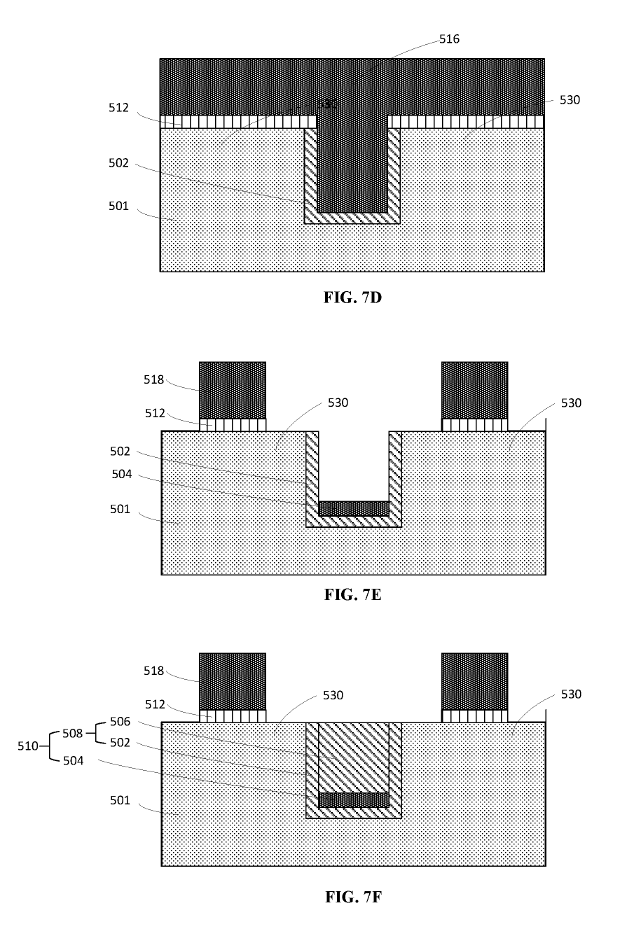

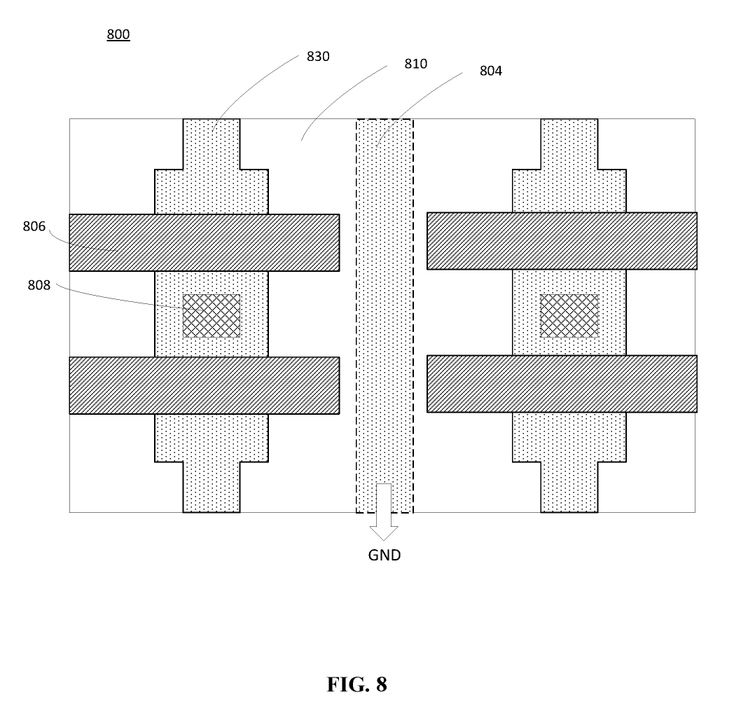

FIG. 6 illustrates a flow diagram of the method of manufacturing the semiconductor device according to one or more exemplary embodiments of this disclosure. FIGS. 7A to 7F illustrate schematic sectional diagrams of the semiconductor device corresponding to a portion of steps of the method as shown in FIG. 6. An explanation is given below by combining FIG. 6 with FIGS. 7A-7F.

To simplify the description, in the description for respective exemplary embodiments according to this disclosure, a detailed description is given below only for a difference between exemplary embodiments, but a repetitive explanation for identical or similar portions is omitted.

As shown in FIG. 6, a step of providing a substrate 602, a step of forming a trench 604, and a step of forming a contact 620 as comprised in the manufacturing method 600 are similar to corresponding steps in the manufacturing method 200 as shown in FIG. 2, and thus explanations therefor are omitted here.

After the trench is formed, at step 606, a first insulating layer 502 is formed in a trench 520. The first insulating 502 fills the trench 520, as shown in FIG. 7A. Optionally, a planarized surface may be formed by the Chemical Mechanical Polishing process.

At step 608, the oxide layer 512 is formed on the substrate 501. As shown in FIG. 7B, the oxide layer 512 overlays the active region 530 and the first insulating layer 502. Optionally, the oxide layer 512 may be planarized by the Chemical Mechanical Polishing process to form a smooth planarized surface. In some exemplary embodiments, the oxide layer 512 may be formed of, such as an oxide. The oxide layer 512 may be formed by the Chemical Vapor Deposition, the thermal oxidation process, or other appropriate technology.

At step 610, an opening 514 down to a predetermined position in the first insulating layer 502 is manufactured from an upper surface of a portion of the oxide layer 512 that overlays the first insulating layer 502, as shown in FIG. 7C. For example, in some exemplary embodiments, the opening 514 may be obtained by any appropriate etching process that is known to the art, which includes but is not limited to, wet etching or dry etching (e.g. plasma etching).

At step 612, a conductive layer 516 is formed on the substrate 501. As shown in FIG. 7D, the conductive layer 516 includes at least a portion filling the opening 514 and a portion overlaying the active region 530.

Thereafter, a selective etching is performed for the conductive layer 516.

In step 614, the first region 504 is formed by etching the conductive layer 516.

In one or more exemplary embodiments, after being etched, the conductive layer 516 located inside the opening 514 is partially or fully reserved. For example, only a portion of the conductive layer 516 located near the bottom of the trench 520 may be reserved. The reserved portion forms the first region 504, as shown in FIG. 7E. It can be understood that, the conductive layer 516 located inside the opening 514 may also be fully reserved, although not illustrated.

At step 616, the gate structure 518 is formed by etching the conductive layer 516.

In one or more exemplary embodiments, at step 616, a selective etching is performed for a portion of the conductive layer 516 that is outside the trench 520 and the oxide layer 512. Therefore, a remaining portion of the conductive layer 516 that is outside the trench 520 forms the gate structure 518, as shown in FIG. 7E.

It is worth noting that, the division of step 614 and step 616 is merely illustrative to facilitate the description. In the practical operation, two steps may be arbitrarily combined, or even combined as a single step. Besides, the two steps are performed in an order that is not limited by the descriptive order, and may be, at least partially, concurrently performed. By forming the gate structure of the active region and the conductive region in the trench with the identical conductive layer, the process may be simplified.

Besides, optionally, in one or more exemplary embodiments, if only a portion of the conductive layer 516 that is in the opening 514 is reserved, then after the first region is formed, the opening 514 may be filled to form the second insulating layer 506. The second insulating layer 506 and the first insulating layer 502 form a second region 508 that encloses the first region 504, as shown in FIG. 7F.

FIG. 8 illustrates a schematic top diagram of a portion of the semiconductor device according to one or more exemplary embodiments of this disclosure. In one or more exemplary embodiments, the semiconductor device may be a Static Random Access Memory (SRAM). However, it is only an example, and this disclosure is not limited thereto. The semiconductor device may be any semiconductor device, for example, an image sensor, or a logic circuit.

FIG. 8 illustrates a trench structure component 810 and active regions 830 separated by the trench structure component 810. The active region 830 may include a gate structure 806 and a connection pad 808 thereof. In particular, the connection pad 808 may be connected to various conductive components as required. In this example, assume that the connection pad 808 is grounded. Besides, the trench structure component 810 further includes a first region 804 that can serve as the wiring. In FIG. 8, a boundary of the first region 804 is denoted by a dotted line to indicate that it is possibly located inside the trench and thus cannot be directly viewed from the top view (for example, the case as shown in FIG. 1)

The first region 804 may be connected to the connection pad 804 through the contact and the metal interconnect layer as shown in FIG. 4D. In this example, the first region 804 can be grounded through the contact. Certainly, the first region 804 may be connected to other external conductive material as required. Accordingly, the first region 804 may serve as the wiring, thus saving a spatial consumption of the wiring on the chip and enhancing the flexibility of design of the chip.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a partially operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. A semiconductor device, comprising:
a substrate, the substrate including a trench structure component and active regions separated by the trench structure component,
wherein, the trench structure component has a trench and a first region and a second region located in the trench, the second region at least encloses a bottom surface and a side surface of the first region, and
the first region is made of a conductive material, and the second region is made of an insulating material.

2. The semiconductor device according to claim 1, wherein,
the second region encloses an entirety of the first region.

3. The semiconductor device according to claim 1, wherein,
the first region is made of a poly silicon material.

4. The semiconductor device according to claim 1, wherein,
the trench structure component further includes a contact formed on the first region.

5. The semiconductor device according to claim 1, wherein,
the first region is set as being grounded.

6. The semiconductor device according to claim 1, wherein,
the active regions are provided with a transistor.

7. The semiconductor device according to claim 1, wherein,
the trench is formed by a Shallow Trench Isolation method.

8. The semiconductor device according to claim 7, wherein,
the semiconductor device is one or more of an image sensor, a memory or a logic circuit.

9. A method of manufacturing a semiconductor device, comprising:
providing a substrate, the substrate including a trench and active regions separated by the trench;
forming a first insulating layer on the substrate, the first insulating layer overlaying a surface of the trench and the active regions; and
forming a first region on the first insulating layer, the first region being located in the trench and made of a conductive material.

10. The method according to claim 9, further comprising:
filling the trench to form a second insulating layer, the second insulating layer overlaying the first region and the first insulating layer.

11. The method according to claim 10, further comprising:
removing portions of the first insulating layer and the second insulating layer that are outside the trench, forming in the trench a second region that encloses the first region,
wherein, the second region includes remaining portions of the first insulating layer and the second insulating layer.

12. The method according to claim 9, wherein forming the first region on the first insulating layer comprises:
forming a first conductive layer on the first insulating layer, and
removing a portion of the first conductive layer to form the first region.

13. The method according to claim 9, wherein,
the first region is made of a poly silicon material.

14. The method according to claim 9, further comprising:
forming a contact on the first region.

15. The method according to claim 9, wherein,
the first region is set as being grounded.

16. A method of manufacturing a semiconductor device, comprising:
providing a substrate, the substrate including a trench and active regions separated by the trench;
filling the trench to form a first insulating layer;
forming an oxide layer on the substrate, the oxide layer overlaying the active regions and the first insulating layer;
forming an opening through the oxide layer and a portion of the first insulating layer;
forming a conductive layer on the oxide layer, the conductive layer overlaying the oxide layer and filling the opening; and
etching a portion of the conductive layer that is in the opening to form a first region on the first insulating layer in the opening.

17. The method according to claim 16, further comprising:
etching a portion of the conductive layer that is on the oxide layer to form a gate structure.

18. The method according to claim 16, further comprising:
filling the opening to form a second insulating layer, wherein the second insulating layer overlays the first region, and forms, with the first insulating layer, a second region that encloses the first region.
